(19) United States
(12) Patent Application Publication
(10) Pub. No.: US 2006/0267625 A1
(43) Pub. Date: Nov. 30, 2006

(54) Active matrix display circuit substrate, display panel including the same, inspection method thereof, and inspection device thereof

(76) Inventor: Yasuhisa Kaneko, Kanagawa (JP)

Correspondence Address: OHLANDT, GREELEY, RUGGIERO & PERLE, LLP, ONE LANDMARK SQUARE, 10TH FLOOR, STAMFORD, CT, 06901, US

(21) Appl. No.: 10/543,229

(22) PCT Filed: Jan. 28, 2004
(86) PCT No.: PCT/JP04/00789

§ 371 Date: Jul. 21, 2006

(30) Foreign Application Priority Data
Feb. 7, 2003 (JP) 2003-031004

(51) Int. Cl. G01R 31/00

(52) U.S. Cl. 324/770

(57) ABSTRACT

An abstract matrix circuit substrate for liquid crystal or EL display having a drive circuit for each of the pixels. In the proximity of each drive circuit, there is provided an optical control switch for performing control so that a current path between the drive circuit and an external wiring is provided when the ON state is set in. During inspection, light is applied to a predetermined optical control switch so as to turn ON the optical control switch and evaluation is performed by measuring the current passing through the optical control switch.

### 1. FIELD OF THE INVENTION

The present invention relates to testing electrical properties during the production of liquid crystal display and organic EL display panels, and, in particular, relates to a probe that is ideal for electrical testing of thin-film transistor (TFT hereafter) arrays, and a display substrate inspection device that uses the same.

### 2. DISCUSSION OF THE BACKGROUND ART

There is a demand for liquid crystal displays that use many pixels and have a larger screen size, and active-matrix systems that use TFTs (Thin Film Transistor) have become the focus of realizing high-image quality in recent years. Moreover, in contrast to liquid crystal displays that require a backlight, self-emitting organic ELs (or OLED (Organic Light Emitting Diode)) have an advantage not seen with liquid crystal displays and development thereof has progressed at a feverish pitch in recent years.

TFT array testing whereby electrical inspection to determine whether or not a completed TFT array has correct electrical operation is performed during the production of a TFT liquid-crystal display or an organic EL display prior to the step whereby the TFT array is formed on a glass substrate, that is, the step whereby liquid crystals are injected or an organic EL is applied, is very important in improving the yield of the final completed product during production of displays. When electrical defects are discovered in a TFT circuit that drives specific pixels during TFT array testing, corrective treatment is performed on the defect if this defect is correctable based on information from the TFT array test. Moreover, when inspections are performed for shipping after a display has been assembled, subsequent steps can be canceled in advance if many defects have been found and the array is evaluated as defective. That is, there is an advantage in that when a defective product is detected early on, the subsequent costly steps of bonding to a color filter and injection of liquid crystals in the case of a liquid crystal display or application of an organic EL in the case of an organic EL display can be canceled.

Nevertheless, a method can be used whereby the surface potential of a liquid crystal is measured in order to inspect a drive circuit for the substrate of a conventional liquid crystal display prior to injecting liquid crystals. That is, liquid crystals are driven by voltage; therefore, the potential of an electrode next to a liquid crystal will change when the drive circuit is operating and a drive circuit can be inspected by measuring the change in the surface potential, even before liquid crystals are injected. However, self-emitting EL displays are a current-driven system; therefore, operation of the active elements in the drive circuit cannot be evaluated unless current is being supplied to each drive circuit. Consequently, the property evaluations performed by a conventional constant-voltage drive circuit of a liquid-crystal TFT array tester cannot be applied to an organic EL display.

Methods whereby a conductor film is temporarily disposed on the surface of an electrode, current is applied to the drive circuit through this thin film, operation is confirmed, and then this thin film is removed are known as means for solving these problems (refer to JP Kokai Unexamined Patent Publication 2002-108,243). Nevertheless, removal of the film used for the inspection takes time and can produce factors that will generate continuous defects between the EL material and the electrode. Methods are known whereby a capacitor is disposed in the drive circuit and the operating state of the active elements is indirectly evaluated by reading the charge applied to the capacitor (refer to JP Kokai Unexamined Patent Publication 2002-32025). However, this method only indirectly evaluates the operation of the elements and does not directly confirm the operation of active elements. Therefore, a more reliable evaluation method is necessary. Methods are also known whereby a display substrate is exposed to light and the leakage current is increased in order to inspect the substrate (JP Kokai Unexamined Patent Publication 7[1995]-151,808). Nevertheless, the leakage current cannot be quantitatively controlled; therefore, measurement accuracy cannot be guaranteed if there is a threshold value for the current necessary for measurement. As a result, the first object of the present invention is to solve these problems and provide a display substrate with which highly reliable inspection is possible, as well as an inspection method and inspection device that use the same.

On the other hand, a completed EL display differs from a liquid crystal display in that it comprises many EL elements that serve as a light source. That is, the liquid crystals used in a flat panel display do not themselves emit light; therefore, in many cases these displays have a structure whereby uniform light intensity is applied over the entire display surface using as the light source a cold cathode tube or a white LED and a diffusion plate. The liquid crystals also act as a filter that adjusts the light intensity thereof. Consequently, the properties of the individual EL elements of EL displays change over time under the influence of external factors and such phenomena, and when there are fluctuations in the emission intensity thereof, the properties that allow for practical use of the display cannot be maintained. Consequently, methods for inspecting the properties of a completed display based on a pixel unit and a control of the emission of light from each element based on the results thereof are preferred. Consequently, a second object of the present invention is to provide such inspection means.

Furthermore, there are also cases where it is preferred that liquid crystal or EL displays comprise a display function and part of the input means for a computer or other information terminal. For instance, touch panel and pen input-type devices are being marketed and used for practical purposes. In this case, additional production processes can be omitted as long as the display substrate itself can be equipped with such additional functions, and this makes production very efficient. In addition, as previously mentioned, EL displays are self-emitting devices; therefore, furnishing such devices with a simple scanning function and other functions is also being considered in order to develop EL displays as input devices. Consequently, a third object of the present invention is to provide a display substrate with additional functions as options for conventional displays.

### SUMMARY OF THE INVENTION

The present invention provides novel inspection means for solving the above-mentioned problems. By means of the present invention, optical control switches are formed close to the active elements of each drive circuit of a display substrate. The electrical path of the optical control switches is turned on only when the switches are exposed to light. That is, a current is allowed to flow through optical control switches of the drive circuit only when these optical control switches are exposed to light. The operation of the active elements of the drive circuit can be directly evaluated by isolating this current to the outside through a gate line or other wiring and then measuring this current.

That is, the present invention provides a method for inspecting the operation of a pixel drive circuit disposed on a display circuit substrate, this method being characterized in that it comprises a step for applying a current to each drive circuit corresponding to a pixel unit on a display circuit substrate, with this current being large enough to confirm the operation of predetermined active elements in the drive circuit; a step for irradiating light on an optical control switch connected to a predetermined position on the drive circuit in order to turn on the optical control switch; and a step for measuring the current that passes through the optical control switch when the optical control switch is ON.

The present invention provides an active matrix display circuit substrate that is used for liquid crystal or EL displays and that has switches or detectors that respond to light for inspection or other treatment. Switches or detectors are disposed for each drive circuit unit corresponding to each pixel of the display. The inspection switches that respond to light are assigned in-series to predetermined active elements of the drive circuit units. Inspection is performed before the liquid crystals are injected or the EL material is applied. An insulated state of high resistance is retained when the switches are not being used, that is, when the switches are OFF. The switches are irradiated by light in this state for the necessary time interval such that current of a predetermined value is applied to the drive circuit. As a result, the switches are turned on and the current is output from the actuated active elements through the switch to the outside. It is possible to directly evaluate the operation of the drive circuit by measuring the output current.

The detectors of the circuit substrate of the present invention can receive light from any EL element when the display panel is in a completed state after injecting liquid crystals or applying EL material. Each of the detectors is disposed so as to corresponding to one pixel; therefore, it is possible to confirm whether or not light sources correspond to each pixel are properly operating by using the detectors to evaluate the light intensity of the light emitted from the EL elements of each pixel.

Furthermore, the detectors of the circuit substrate of the present invention can detect light received from the inside or the outside when the display panel is completed. For instance, when an object is disposed near the panel surface, the light emitted by an EL element of a predetermined pixel can be detected by a detector that has been disposed for a drive circuit corresponding to another pixel that is nearby. Consequently, if this object is a human finger or a part of a pin, it can be used as a pointer or a simple scanner capable of reading patterns and the like on a flat surface that is near the display.

It is preferred that the above-mentioned switches and detectors that respond to light be a common element. As a result, a display substrate having an additional useful functions and a relatively large display panel opening surface area, as well as a display panel comprising this display substrate, are provided by the present invention. The switches and detectors can be formed by a series of semiconductor production processes whereby drive circuits are formed and, as a result, the switches and detectors can be housed inside the drive circuit.

That is, the present invention provides an active matrix display circuit substrate, further characterized in that optical control switches for providing control such that a current path is provided between drive circuits corresponding to each pixel and external wiring when the display is ON are disposed near each drive circuit on an active-matrix display circuit substrate for liquid crystal or EL displays having drive circuits corresponding to each pixel.

Preferably, the optical control switches are connected in-series to the active elements in the drive circuits and a drive circuit at a predetermined position is actuated and the corresponding optical control switch is turned on by light from the outside so that the drive current can pass through the optical control switch and the current passing through the switch can be measured to check the operation of predetermined active elements in the drive circuit.

Preferably, the active-matrix display circuit substrate is a substrate for EL displays and the optical control switches are used as detection elements for directly detecting light from EL emission elements disposed on the active-matrix display circuit substrate.

Preferably, the active-matrix display circuit substrate is a substrate for EL displays and the optical control switches are used as detection elements for detecting reflected light by allowing light from the EL emission elements disposed on the active-matrix display circuit substrate to be reflected by an outside object.

Preferably, the optical control switches in the active-matrix display circuit substrate are used as detection elements for detecting the emission of light from an external pointing device.

Preferably, the optical control switches are made such that output is applied to any wiring disposed in a drive circuit corresponding to another pixel unit adjacent to the pixel unit to which the optical control switch in question is assigned.

Preferably, the optical control switches are made such that output is applied to the gate line in a drive circuit corresponding to another pixel unit adjacent to the pixel unit to which the optical control switch in question is assigned.

Preferably, the optical control switches are made such that output is applied to wiring added to the drive circuit.

Preferably, the optical control switches are photoconductive switches.

Preferably, the optical control switches are made such that resistance is applied in-series.

Preferably, the optical control switches comprise a semiconductor layer, the base of which is the same semiconductor material as the drive circuit.

Preferably, the semiconductor material is amorphous silicon or polycrystalline silicon.

The present invention further provides a display panel characterized in that it comprises any of the above-mentioned active-matrix display circuit substrates and an EL material layer disposed on this circuit substrate.

The present invention further provides a method for inspecting the operation of a pixel drive circuit disposed on an active-matrix display circuit substrate for liquid crystal or EL displays, this method being characterized in that it comprises a step for applying a current to a each drive circuit corresponding to pixel units of the circuit substrate prior to injection of liquid crystals or application of an EL material, with this current being large enough to confirm the operation of predetermined active elements in a drive circuit; a step for exposing to light an optical control switch connected to a predetermined position on the drive circuit in order to turn on the optical control switch; and a step for measuring the current that passes through the optical control switch when the optical control switch has been turned on.

Preferably, the step for applying current to the drive circuit, the step for exposing the optical control switch to light, and the step for measuring current are performed in succession on the drive circuit such that light scans the circuit substrate.

Preferably, the light is converged light that is to be irradiated onto an optical control switch corresponding to only one pixel unit.

Preferably, the light is irradiated onto optical control switches of the drive circuits corresponding to a plurality of pixel units in one row or a plurality of rows corresponding to pixel units in matrix form.

Preferably, the light irradiation time is set such that a charge can pass through the active elements, with this charge being large enough to confirm that the active elements are driven via exposure to light within a unit of time.

The present invention further provides a device for inspecting an active-matrix display circuit substrate for a liquid crystal or EL display, further characterized in that it comprises a support member for supporting the active matrix display circuit substrate before liquid crystals are injected or an EL material is applied; a power source for applying a current to each pixel drive circuit on the display circuit substrate, with this current being large enough to confirm the operation of pre-determined active elements in a pixel drive circuit; a light source for exposing to light optical control switches obtained by connection to each pixel drive circuit on the display circuit substrate; and a measurement means for measuring electrical properties when the optical control switches have been exposed to light and turned on.

Preferably, the light source is a laser light source.

Preferably, the measurement means are made such that the current flowing through the optical control switches is measured.

### BRIEF DESCRIPTION OF THE DRAWINGS

FIG. 1 is a general sketch of the structure of a TFT (thin-film transistor) active-matrix display circuit substrate for a typical organic EL display.

FIG. 2 is a general sketch showing the structure of a circuit substrate that is the first embodiment of the present invention.

FIG. 3 is a plan view showing the general layout of each structural element of the circuit of a pixel unit.

FIG. 4 is a general sketch of the cross section of the layout showing each structural element of the circuit of a pixel unit.

FIG. 5 is a general sketch similar to FIG. 2 showing the circuit substrate that is the second preferred embodiment of the present invention.

FIG. 6 is a general plan view similar to FIG. 3 showing the circuit substrate of a second embodiment of the present invention.

FIG. 7 is a cross section similar to FIG. 4 showing the circuit substrate that is the second embodiment of the present invention.

FIG. 8 is a drawing showing the device for inspecting TFT display substrates before applying an EL material that is a preferred embodiment of the present invention.

FIG. 9 is a plan view showing the details of the substrate support apparatus.

FIG. 10 is a side view showing the details of the light irradiating device.

FIG. 11 is an explanatory drawing showing the procedure of the display tests.

FIG. 12 is a drawing that describes an example of using a display panel comprising the display substrate of the present invention.

FIG. 13 is a drawing that describes another example of using a display panel comprising the display substrate of the present invention.

### DETAILED DESCRIPTION OF THE PREFERRED EMBODIMENT

The active-matrix display circuit substrate, the display panel comprising the same, the inspection method thereof, and the inspection device thereof that are the preferred embodiments of the present invention will now be described in detail while referring to the attached drawings.

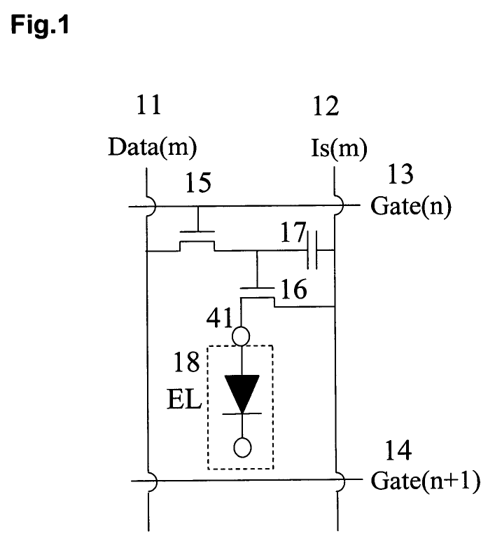

FIG. 1 is a drawing showing the structure of a TFT (thin-film transistor) active-matrix display circuit substrate for a typical organic EL display. The drawing shows a circuit corresponding to a single pixel. Wirings 11, 12, and 13 are the data line (m), the power line, and the gate line (n). These lines define the pixel units of the drive circuits of the display. TFT (thin-film transistors) 15 and 16 and a capacitor 17 are disposed for each pixel unit. As shown in the figure, EL material 18 is applied over an electrode 41 that is positioned in front of the drain of the thin-film transistor of the circuit and formed along the substrate surface. That is, EL material 18 is made such that light is emitted due to a current that passes through thin-film transistor 16.

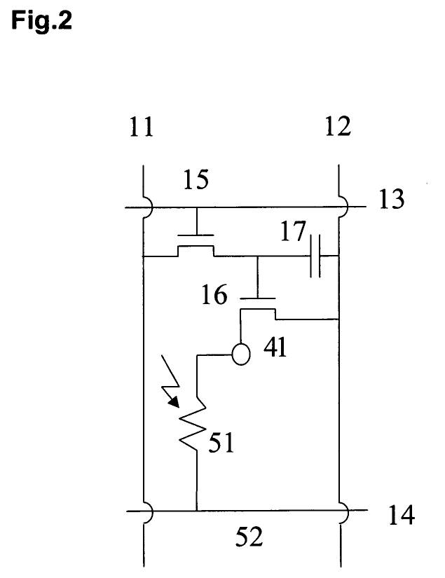

As described above, the present invention provides a method for inspecting a thin-film transistor substrate prior to applying EL material 18. Therefore, the present invention makes it possible to create a current path in the absence of EL material 18 in order to perform an inspection. FIG. 2 is a general drawing showing the structure of a circuit substrate that is the first preferred embodiment of the present invention. As shown in the drawing, an optical control switch 51 is disposed such that electricity is conducted to electrode 41. This switch 51 is connected in-series to thin-film transistor 16 and the other end of switch 51 is connected to a gate line (n+1) of the adjacent drive circuit unit. Consequently, when switch 51 is on, electricity can pass through the active elements of thin-film transistor 16 and switch 5, and the output current can be measured from the output coming from gate line 14 of an adjacent drive circuit. That is, a drive circuit can be confirmed to be capable of normal operation with no pixel defects as long as the appropriate current output can be detected when a drive circuit corresponding to a predetermined pixel is selected.

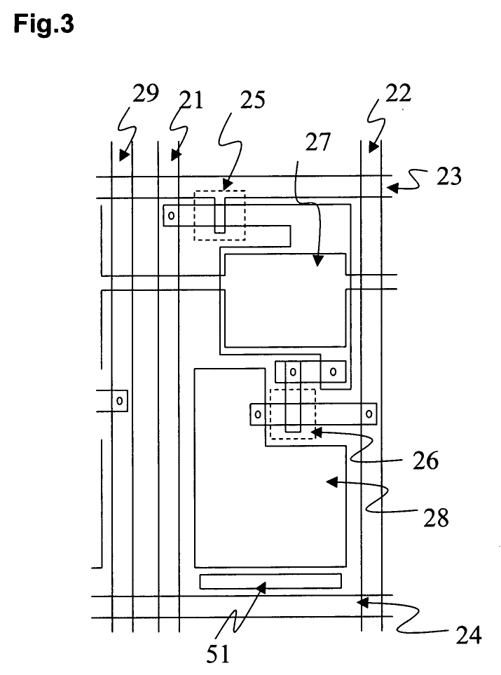

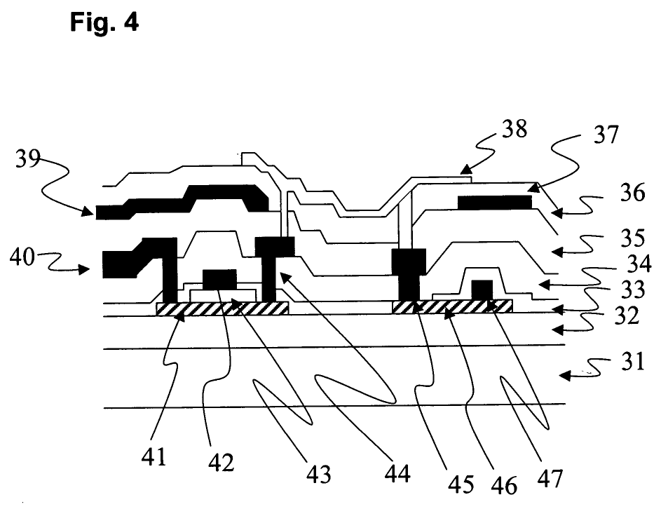

A typical example of optical control switch 51 is a photoconductive switch. A specific example of the structure of a photoconductive switch is represented in FIGS. 3 and 4. FIG. 3 is the plan view showing the layout of each structural element of the circuit of each pixel unit in FIG. 1. Moreover, FIG. 4 is the cross section of the same. References 21, 22, and 23 in FIG. 3 are the data line, power line, and gate line of the pixel unit, respectively. A power line 29 of the pixel unit, adjacent in a transverse direction and a gate line 24 of a pixel unit adjacent in a longitudinal direction are also shown in the figure. Reference 27 in the figure shows a capacitance electrode and reference 28 shows the ITO electrode touching the EL material. Reference 51 shows the optical control switch. As shown in the drawing, switch 51 is formed as a long, thin component extending in the lengthwise direction of gate line 24 between ITO electrode 28 and gate line 24.

The specific layered structure of a circuit comprising each circuit element is shown in the cross section in FIG. 4. References 31, 32, 33, 34, 35, 36, 37, and 38 indicate a glass substrate, a first insulation layer, a second insulation layer, a third insulation layer, a fourth insulation layer, a fifth insulation layer, a light-masking metal layer, and the ITO electrode, respectively. Reference 41, 42, 43, 44, 45, 46, and 47 show a semiconductor thin film, a gate electrode, an insulation layer, a drain wiring, a metal electrode, a photoconductive switch, and a gate line, respectively. As shown in the drawing, the principal parts of the photoconductive switch are on the bottom side of gate line 47. However, they are made from the same material as semiconductor thin film 41 comprising the thin-film transistor; therefore, the production process is not complex. Metal electrode 45 extends up in the direction of height and joins with ITO electrode 38. The circuit structure shown in FIG. 2 is thereby realized.

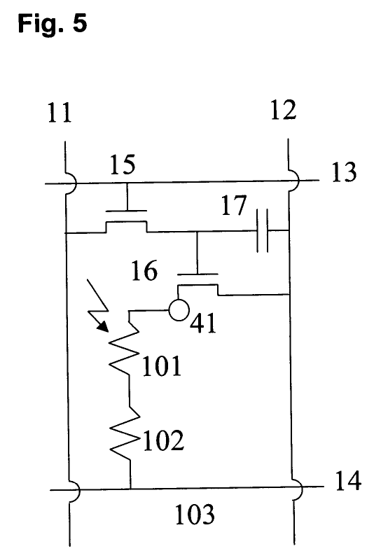

The structure of the circuit substrate that is the second embodiment of the present invention is shown in FIGS. 5 through 7. A general drawing similar to FIG. 2 is shown in FIG. 5. This embodiment differs from the first embodiment in that a resistor 102 is added in-series with an optical switch 101. The current-voltage properties of the photoconductive switch are usually nonlinear and change to linear at the transistor voltage, but current becomes saturated at a higher voltage. This nonlinear property limits the TFT test items. That is, when measuring the current value when voltage is applied continuously within a certain range, the effect of the properties of the photoconductive switch may be disregarded. Therefore, there is an advantage in that this effect can be eliminated by the in-series connection of resistor 102 having a resistance sufficiently larger than photoconductive switch 101.

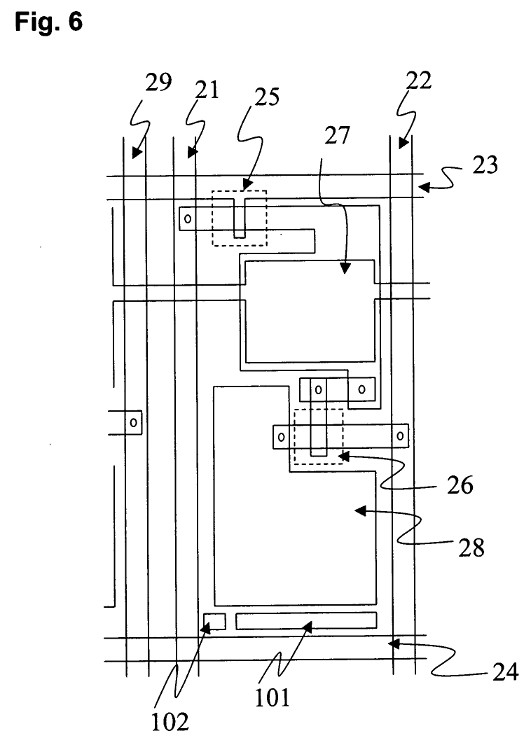

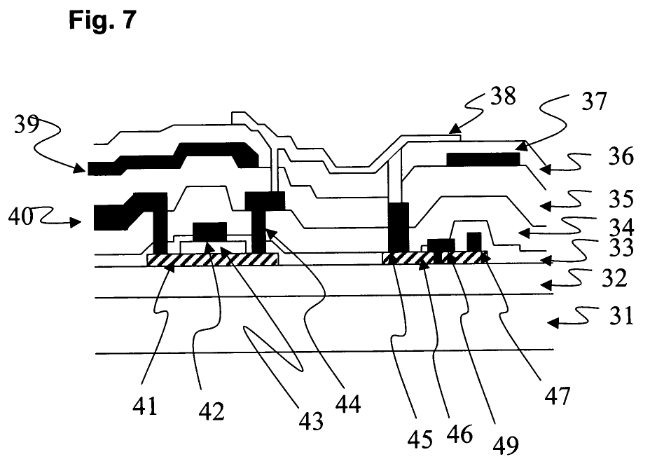

FIGS. 6 and 7 are drawings that describe a second embodiment of the present invention and are a plan view similar to FIG. 3 and a cross section similar to FIG. 4, respectively. According to FIG. 6, resistor 102 is considered an adjacent pixel unit and can be disposed close to gate line 24, which outputs current when optical control switch 51 is ON. FIG. 7 shows an example of the formation of the resistor. As shown in the drawing, resistor 102 can be formed by insulating semiconductor layer 46 with an insulator and forming a metal layer 49. However, the method for forming resistor 102 is not limited to this method and another method can be used. For instance, the resistor can be formed by adjusting the amount of doping impurities added to the semiconductor layer.

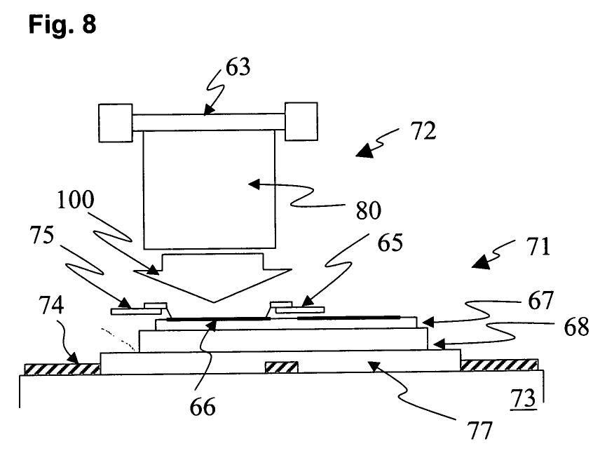

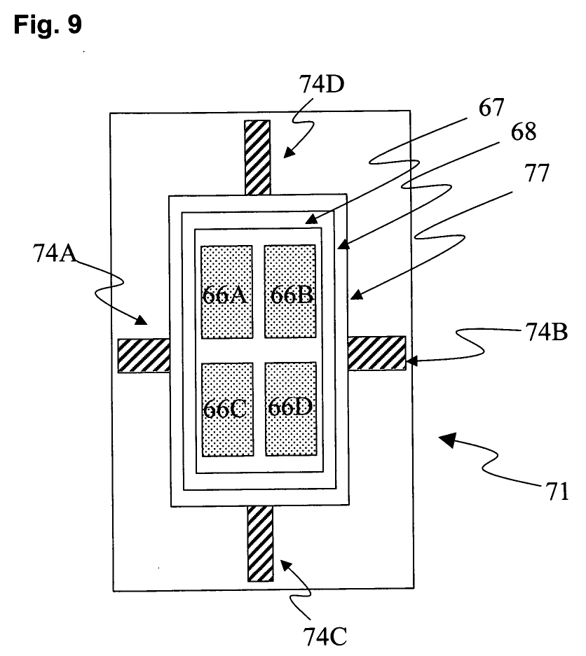

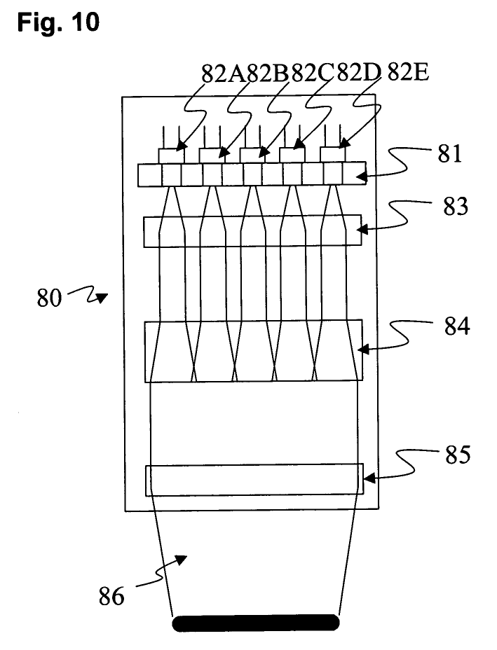

FIG. 8 shows a device for inspecting a TFT display substrate before applying any EL material that is a preferred embodiment of the present invention. Reference 71 is a substrate support device for positioning the display substrate. Reference 72 indicates a light irradiation device. The details of substrate support device 71 are shown as a plan view in FIG. 9 and the details of light irradiation device 72 are shown as a side view in FIG. 10.

Substrate support device 71 has a movement mechanism 68 disposed on top of a stationary table 73 and this can support substrate 67, including display parts 66, disposed on top of the table. FIGS. 8 and 9 show examples of a substrate with four display parts 66. Movement mechanism 68 can move up and down and to the right and left or in a rotating direction on top of stationary table 73; therefore, the display under test 66 can be moved to a predetermined position as needed on stationary table 73. A probe 65 is disposed at display part 66 to be measured. Probe 65 supplies current to the substrate and contacts electrodes disposed at the substrate under test in order to confirm the output. This electrode is preferably disposed for inspection.

FIG. 8 includes a light irradiation means 80 supported by an irradiation device support means 63. Support means 63 can keep irradiation means 80 at an anchored position, but when necessary, it can also move. As shown in FIG. 10, radiation means 80 comprises a plurality of semiconductor lasers represented by references 82A through 82E, a heat sink 81, a collimator lens 83, a beam shape converter 84, and a focusing lens 85. The structure from semiconductor lasers 82A through 82E to focus lens 85 is employed primarily for the purpose of a uniform mixing of light and can be substituted with other means. By means of the present embodiment, this structure is used to make a long, thin beam with a width of approximately 100 μm and a length of approximately 10 cm. As a result, for instance, it is possible to a irradiate light onto each row and evaluate the operation of the drive circuit.

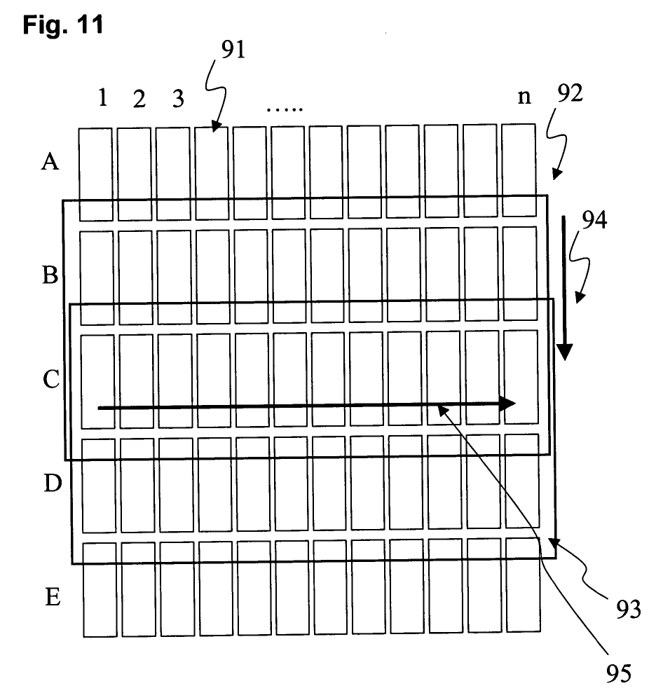

FIG. 11 is an explanatory diagram showing the display test procedure. For instance, the above-mentioned long, thin beam is shaped such that it is always irradiated over all rows of pixels and in at least two columns. Take, for instance, an inspection of all of the pixels in column C. That is, testing will be performed beginning with (C,1) to (C,n). The photoconductive switches are disposed at a relatively low position in each pixel. First, light spots for testing pixel (C,1) are positioned at a position 92 once the testing of pixel (C,1) is completed and the test is then performed in the order of (C,2) . . . (C,n). The light beam moves forward in a direction 94 during this time. The light beam must move one column at a time such that it is at position 93 when the last pixel (C,n) is tested so that light always touches the photoconductive switches in line c. (In the figure, the position of the beam is shown slightly shifted horizontally in order to facilitate the description.) Consequently, when the length in the longitudinal direction for one pixel is 1 [m], the test time for one pixel is t[s], and the number of pixels per line is m, the speed s of the beam is represented by s=1/(t m)[m/s]. It is possible to continuously move the light beam and curtail the test time by using this method. However, this method is just one example and various other methods can be considered. Moreover, the beam shape is not limited to a long, thin beam and other beam shapes can be used. The method whereby a beam with a small diameter is used for scanning can also be used.

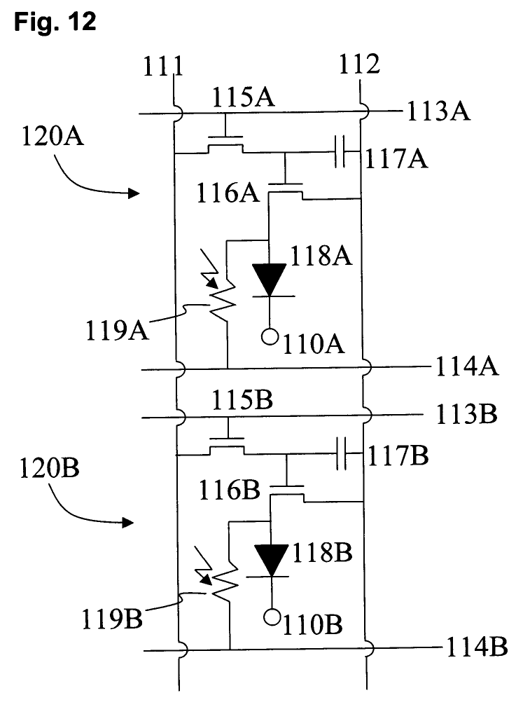

FIG. 12 is a drawing that describes an example of the use of a display panel comprising a display substrate of the present invention. As previously described, the display substrate of the present invention can comprise optical switches that can be used as pixel detectors; therefore, the present invention provides means for eliminating variations in brightness among pixels using the same optical switches. FIG. 12 shows a circuit diagram corresponding to two adjacent pixels.

That is, by means of this embodiment, the light intensity is measured and brightness is adjusted based on this intensity using the photoconductive switches and light detecting elements in order to control any variations in brightness between these pixels. Light intensity is not continuously measured when the display is on; it is measured when the display is turned on or at any other time as needed. For instance, consider the case where an EL element 118A of a pixel 120A emits light and the light is received at a light detector 119B of a pixel 120B. In this example, the elements on the sides of the detector 119A or 119B are connected to newly disposed detection lines 114A and 114B, respectively. The EL element of pixel 120A is charged such that voltage V1 is applied to a capacitor 117A so that a TFT 115A is turned ON and a TFT 116A is turned ON (light is emitted). Detection line 114A is in an open state at this time. On the other hand, the voltage at pixel 120B with which a capacitor 117B is charged is not enough for an EL element 118B to emit light and voltage V2 is applied. However, some current can flow between the TFT drain and source under this voltage. Light detector 119B of adjacent pixel 120B receives light from EL element 118A in this state; the current that flows through a TFT 116B as a result of a reduction in resistance associated with this light is measured by light-receiving terminal 114B and the amount of light at pixel 120A can thereby be detected. Based on this method, the intensity of light is measured at the adjacent pixel when one pixel is emitting light that is so weak that it can be disregarded; this intensity is compared with the predetermined intensity that is necessary per pixel, and when there is a difference, the voltage applied to capacitor 117A is adjusted such that the intensity becomes the predetermined intensity. Display stability can be improved by measuring the intensity of all pixels by this method. Furthermore, as with the above-mentioned embodiments, the photoconductive switches can be used for testing the operation of substrates before the organic EL has been applied and the organic EL display panel can then be completed.

Detecting the presence or movement of an external device that is near the display panel will now be considered as another use of the display substrate of the present invention. That is, a touch panel, pen input, or simple scanner can be realized based on this theory. A touch panel or scanner function is realized by using a light detector or an optical switch to detect the light that has been irradiated from an EL element as the light source and then reflected by an object. Two adjacent pixels can be used for emission of light and reception of light, respectively, as previously described. The detection means of the pixel on the light-receiving side can be such that the current is transferred externally by other wiring added to the display substrate. This detection means can also be used for the inspection of a display substrate before injecting the liquid crystals or applying the EL material.

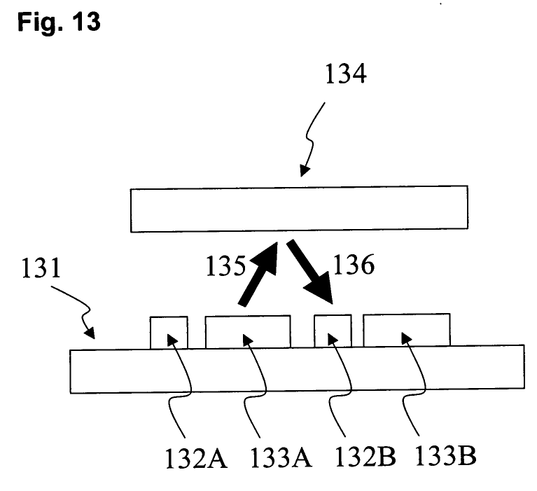

FIG. 13 shows the use of this display substrate. The light that has been irradiated by a light-emitting element 133A of an EL element of a pixel A (reference 135) is reflected by an object 134 (reference 136) and received by a photoconductive switch 132B of a pixel B. The EL elements of the display are in three colors, red, blue and green. Therefore, it is not necessary to place a color filter in front of the light detector as it is with a conventional scanner. Moreover, it is necessary to measure the properties of the light that is received in the absence of the object under test in order to cancel the light that is received by the switch without passing through an object. The same method can be applied to a touch panel. Once the intensity of light reflected from an object is detected, signal processing is performed with an operating system or a display control mechanism. A particularly obvious improvement in performance can be expected when this method is used for a lap-top computer. This method is promising for multifunction PCs that will not be accompanied by an increase in volume or weight. Furthermore, the light-receiving and light-emitting pixels can be adjacent, but they are not necessarily adjacent to one another.

The active matrix display circuit substrate of the present invention, the display panel including the same, the inspection method thereof and the inspection device thereof have been described in detail. However, it goes without saying that these are only examples, the present invention is not limited to these examples, and various changes and modifications can be made by persons skilled in the art.

What is claimed is:

1. An active matrix display circuit substrate, wherein the optical control switches for providing control such that a current path is provided between drive circuits corresponding to each pixel and external wiring when the display is ON are disposed near each drive circuit on an active-matrix display circuit substrate for liquid crystal or EL displays having drive circuits corresponding to each pixel.

2. The active-matrix display circuit substrate according to claim 1, wherein said optical control switches are connected in-series to the active elements in the drive circuits and a drive circuit at a predetermined position is actuated and the corresponding optical control switch is turned on by light from the outside so that the drive current can pass through the optical control switch and the current passing through the switch can be measured in order to check the operation of predetermined active elements in the drive circuit.

3. The active-matrix display circuit substrate according to claim 1, wherein said active-matrix display circuit substrate is a substrate for EL displays and the optical control switches are used as detection elements for directly detecting light from EL emission elements disposed on the active-matrix display circuit substrate.

4. The active-matrix display circuit substrate according to claim 1, wherein said active-matrix display circuit substrate is a substrate for EL displays and the optical control switches are used as detection elements for detecting reflected light by allowing light from the EL emission elements disposed on the active-matrix display circuit substrate to be reflected by an external object.

5. The active-matrix display circuit substrate according to claim 1, wherein said optical control switches in the active-matrix display circuit substrate are used as detection elements for detecting the emission of light from an external pointing apparatus.

6. The active-matrix display circuit substrate according to claim 2, wherein said optical control switches are made such that their output is applied to any wiring disposed in a drive circuit corresponding to another pixel unit adjacent to the pixel unit to which the optical control switch in question is assigned.

7. The active-matrix display circuit substrate according to claim 2, wherein said optical control switches are made such that their output is applied to the gate line in the drive circuit corresponding to another pixel unit adjacent to the pixel unit to which the optical control switching in question is assigned.

8. The active-matrix display circuit substrate according to claim 1, wherein said optical control switches are made such that their output is applied to wiring added to the drive circuit.

9. The active-matrix display circuit substrate according to claim 1, wherein said optical control switches are photoconductive switches.

10. The active-matrix display circuit substrate according to claim 1, wherein said optical control switches are made such that resistance is applied in-series.

11. The active-matrix display circuit substrate according to claim 1, wherein said optical control switches comprise a semiconductor layer, the base of which is the same semiconductor material as the drive circuit.

12. The active-matrix display circuit substrate according to claim 11, wherein said semiconductor material is amorphous silicon or polycrystalline silicon.

13. A display panel which comprises: an active matrix display circuit substrate, wherein the optical control switches for providing control such that a current path is provided between drive circuits corresponding to each pixel and external wiring when the display is ON are disposed near each drive circuit on an active-matrix display circuit substrate for liquid crystal or EL displays having drive circuits corresponding to each pixel; and an EL material layer disposed on the circuit substrate.

14. A method for inspecting the operation of a pixel drive circuit disposed on an active-matrix display circuit substrate for liquid crystal or EL displays, said method comprising:
providing current to drive circuits corresponding to each pixel unit of the circuit substrate prior to injection of liquid crystals or application of an EL material, with this current being large enough to confirm the operation of a predetermined active element in a drive circuit;
exposing to light an optical control switch connected to a predetermined position on the drive circuit and turning on the optical control switch; and
measuring the current passing through the optical control switch when the optical control switch has been turned on.

15. The method according claim 14, wherein the step for applying current to the drive circuit, the step for exposing the optical control switch to light, and the step for measuring current are performed in succession on the drive circuit such that the light scans the circuit substrate.

16. The method according to claim 14, wherein the light is converged light that is to be irradiated onto an optical control switch corresponding to one pixel unit only.

17. The method according to claim 14, wherein the light is irradiated onto optical control switches of the drive circuits corresponding to a plurality of pixel units in one row or a plurality of rows corresponding to pixel units in matrix form.

18. The method according to claim 14, wherein the light irradiation time is set such that a charge can pass through the active elements, with this charge being large enough to confirm that the active elements are driven via exposure to light within a unit of time.

19. An apparatus for inspecting an active-matrix display circuit substrate for a liquid crystal or EL display, said apparatus comprising:
a support member for supporting the active matrix display circuit substrate before liquid crystals are injected or an EL material is applied;
a power source for applying a current to each pixel drive circuit on the display circuit substrate, with this current being large enough to confirm the operation of pre-determined active elements in a pixel drive circuit;
a light source for exposing to light optical control switches obtained by connection to each pixel drive circuit on the display circuit substrate; and
a measurement means for measuring the electrical properties when the optical control switches have been exposed to light and turned on.

20. The inspection apparatus according to claim 19, wherein said light source is a laser light source.

21. The inspection device according to claim 19, wherein said measurement means is made such that the current flowing through the optical control switches is measured.
